(19) United States
(12) Patent Application Publication
(10) Pub. No.: US 2010/0163095 A1
(43) Pub. Date: Jul. 1, 2010

(54) SOLAR POWER PLANT

(75) Inventor: Josef Marx, Paderborn (DE)

Correspondence Address: PATENT CENTRAL LLC;Stephan A. Pendorf, 1401 Hollywood Boulevard, Hollywood, FL, 33020, US

(73) Assignee: Loeseke & Marx GmbH & Co. KG, Paderborn (DE)

(21) Appl. No.: 12/376,813

(22) PCT Filed: Jun. 22, 2007
(86) PCT No.: PCT/DE07/01152

§ 371 Date: Feb. 9, 2009

(30) Foreign Application Priority Data
Aug. 7, 2006 (DE) 20 2006 012 167.6

(51) Int. Cl. H01L 31/042; F16M 13/00

(52) U.S. Cl. 136/244; 248/288.11

(57) ABSTRACT

The invention relates to a solar power plant comprising a solar module system with a plurality of solar modules arranged in a plane for converting solar radiation into electrical energy, and comprising an adjusting device for the sun-position-dependent tracking of the solar module system, wherein the solar module system is mounted such that it can be pivoted at least about one pivot axis, wherein the solar modules are mounted with their edges at least in part in a J-shaped holding profile.

The invention concerns a solar power plant comprising a solar module system, in which a plurality of solar modules are provided arranged in a plane for conversion of solar radiation into electrical energy, and with an adjustment device for orienting the solar module system depending upon the position of the sun, wherein the solar module system is mounted for pivoting about at least one pivot axis.

DE 103 01 550 A1 discloses a solar plant for production of electrical energy from solar energy, which includes a solar module system with a plurality of solar modules arranged in a plane. The solar module system is guided to follow the sun using an adjustment device, so that an optimal orientation of the solar modules towards the sun is always established. For securing the solar modules, until now these have been secured to a carrier using threaded fasteners.

It is the task of the present invention to further develop a solar plant in such a manner that the mounting of the solar modules in the solar module system can be simplified.

For solution of this task the invention is characterized, in combination with the pre-characterizing portion of patent claim 1, thereby, that the solar modules are mounted at least partially with their edge-side in a J-shaped bracket.

The particular advantage of the invention in comprised therein, that by the J-shaped bracket, on the one hand, a sufficient stability is ensured, in order to secure the plurality of relatively heavy solar modules, and, on the other hand, a simple securing of the solar modules is accomplished. For easy assembly the solar modules can be slid into a groove provided by the shape of the mounting bracket, until they have achieved the intended mounted position. Therein the groove of the J-shaped holder bracket serves as a guide.

According to a preferred embodiment of the invention the J-shaped bracket includes, on the one hand, a channel-shaped stabilizing section and, on the other hand, a groove section for receiving an edge of the solar module. The stabilizing section preferably joins an area of the groove section into which a backside of the solar module is provided. The stabilizing section is section with such a breadth, that the solar module is maintained in a plane, secure against bending. The stabilizing section serves at the same time as a stiffener or reinforcement or, as the case may be, an elongation of a lobe of the groove section lying against the backside of the joint.

According to a further development of the invention the groove section of the J-shaped bracket includes two parallel edge lobes, which are oriented in the same direction. Elongation lines of the edge lobes exhibit such a separation from each other, that the solar module can be slid in between the edge lobes with free play. The edge lobes thus serve, in addition to the securing function, also for guidance of the solar modules during the assembly thereof.

Further advantages of the invention can be seen from the further dependent claims.

Illustrative embodiments of the invention are described in greater detail in the following on the basis of the figures.

There is shown:

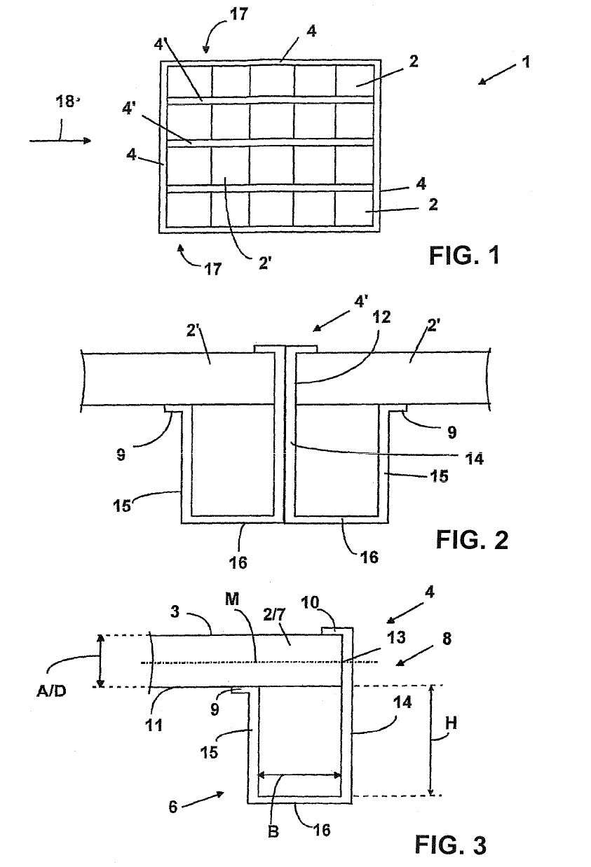

FIG. 1 a top view upon a solar module system with a plurality of solar modules arranged on a plane, which, along a common outer edge are surrounded by a J-shaped bracket,

FIG. 2 a cross-section through a twin-J-bracket, which is provided in a central area of the solar module device, and

FIG. 3 a cross-section through a J-shaped bracket, which is provided at an edge area of the solar module system.

A solar plant for production of electrical energy is comprised essentially of a solar module system 1, which includes a plurality of plate-shaped solar modules 2 arranged in a plane, and of a not-shown adjusting device for orienting the solar module system according to the position of the sun. The solar module system 1 is preferably mounted pivotable about two pivot axis perpendicular to each other, so that the solar module device can be adjusted to maintain an optimal angle for receiving the solar radiation on a top side 3 of the solar module 2.

The solar modules 2 arranged in the manner of a checkerboard are held by a J-shaped bracket 4, 4′, which circumscribes the solar modules 2 around the edges.

In FIG. 2 a twin-J mounting bracket 4′ is shown, which serves to receive two adjacent solar modules 2. The twin-J mounting bracket 4′ is formed of two J-shaped mounting brackets 4, which can be joined to each other in reverse orientation on first side walls 14, for example by screwing together. The single J-shaped mounting bracket 4 shown in FIG. 3 is basically provided around the edges of the solar module device 1 (solar module surface) and follows along the edge-orientation of the solar module system 1.

The J-shaped mounting bracket 4 is comprised of a channel-shaped stabilizing section 6 and a groove section 8 for receiving the edge 7 of the solar module 2.

The groove section 8 includes a lower edge lobe 9 and an upper edge lobe 10, between which the edge 7 of the solar module 2 is positioned. In the assembled condition a backside 11 of the solar module 2 lies with its edge area 7 on the lower edge lobe 9. The upper edge lobe 10 lies on the upper side 3 of the solar module 2. The narrow edge 12 of the solar module 2 lies against a groove wall 13 of the groove section 8, which is unitarily connected on the one side with the upper edge lobe 10 and on the other side with a first sidewall 14 of the stabilizing section 6.

The stabilizing section 6 is U-shaped in cross-section and exhibits besides the first sidewall 14 a parallel thereto second sidewall 15 and a floor wall 16 connecting the first sidewall 14 and the second sidewall 15. The lower edge lobe 9 of the groove section 8 connects to the second sidewall 15 of the stabilizing section 6.

The first sidewall 14 and the second sidewall 15 exhibit such a height H and/or are provided spaced apart from each other at such a breadth B, that the solar module 2 is permanently held stable in the assembled condition. Preferably the height H of the sidewalls 14, 15 or as the case may be the breadth B thereof is greater than half the thickness D of the solar module 2.

The lower edge lobe 9 and the upper edge lobe 10 of the groove section 8 run parallel to each other and parallel to the longitudinal plane M of the solar module 2 or, as the case may be, the solar module system 1. The edge lobes 9, 10 run perpendicular to the narrow side 12 of the solar module 2.

The lower edge lobe 9 and the upper edge lobe 10 have the same orientation, wherein extension lines of the lower edge lobe 9 and the upper edge lobe 10 are such a separation A from each other, that the solar module 2 can be slid in between the lower edge lobe 9 and the upper edge lobe 10 with free play and can be secured in the assembled position. For example, the solar module 2 can be secured to the lower edge lobe 9 by means of lockbolt push pin type securing element or by gluing or by screwing.

The upper edge lobe 10 of the groove section 8 borders the solar module 2 at the upper side 3 and serves in addition as theft protection for the solar module 2 which is held by the mounting bracket 4.

According to a preferred embodiment, the solar modules 2 are respectively edgewise completely surrounded by the mounting bracket 4, wherein inner solar modules 2′ are exclusively surrounded by the twin-J-mounted profiles 4′. Basically, on the opposite edge area 17 of the solar module system 1 simple J-shaped mounting brackets 4 are provided.

According to an alternative embodiment, the narrow sides 12 of adjacent solar modules 2 facing each other can be associated with other guide means. Basically, J-shaped mounting brackets 4 are provided on opposing edge areas 17 of the solar module system 1, completely surrounding the plurality of solar modules 2.

The mounting brackets 4, 4′ can be made of steel, preferably, galvanized, of ST37 or RST52. The height H of the first sidewall 14 and the second sidewall 15 can be in the range of 80 to 200 mm, the breadth B can be in the range of 80 to 150 mm, the spacing A of the extension lines of the edge lobes 9, 10 can be in the range of approximately 70 mm. The length of the J-shaped brackets 4, 4′ can be in the range of 8 to 20 m.

For assembly of the solar module 2, these are edgewise slid along a sliding device 18 in the groove formed by the lower edge lobe 9 and the upper edge lobe 10 into the intended assembly position with play where they are, as desired, fixed. The mounting bracket(s) 4, 4′ are secured to the not shown carrier of the solar module system 1.

1. A solar plant (1), including a solar module system (1) which includes a plurality of solar modules (2) arranged in a plane for transforming solar radiation into electrical energy, and with an adjusting device for allowing the solar module system (1) to follow the position of the sun, wherein the solar module system (1) is mounted for pivoting about at least one pivot axis, and wherein the solar modules (2) are mounted at least partially along an edge in a J-shaped mounting bracket (4, 4′).

2. A solar plant according to claim 1, wherein the J-shaped mounting bracket (4) includes a channel-shaped stabilizing section (6) and a groove section (8) for receiving the edge (7) of the solar module (2).

3. A solar plant according to claim 1, wherein the stabilizing section (6) of the mounting bracket (4) unitarily transitions to the groove section (8).

4. A solar plant according to claim 1, wherein the groove section (8) includes two parallel edge lobes (9, 10) oriented in the same direction, of which the extension lines are spaced apart with such a separation from each other (A) that the solar module (2) can be slid with play between the edge lobes (9, 10) and secured.

5. A solar plant according to claim 1, wherein the edge lobes (9, 10) run perpendicular to the narrow side (12) of the solar module (2) and parallel to the longitudinal middle plane (M) of the solar module (2).

6. A solar plant according to claim 1, wherein the stabilizing section (6) includes a floor wall (16) and a first side wall (14) extending from the floor wall (16) and a second side wall (15), the breadth of separation (B) to each other and/or the height (H) being greater than half the thickness (D) of the solar module.

7. A solar plant according to claim 1, wherein the groove (13) of the groove section (8) extends in the plane of elongation of the first sidewall (14) of the stabilizing section (6).

8. A solar plant according to claim 1, wherein a lower edge lobe (9) of the groove section (8) connects with the second side wall (15) of the stabilizing section (6) and the upper edge lobe (10) of the groove section (8) connects to the first sidewall (14) of the stabilizing section (6).

9. A solar plant according to claim 1, wherein the lower edge lobe (9) is associated with a fastening element for securing the solar module (2).

10. A mounting bracket according to claim 1 for securing a solar module (2).
